(19) United States
(12) Patent Application Publication
(10) Pub. No.: US 2009/0290303 A1
(43) Pub. Date: Nov. 26, 2009

(54) BATTERY COVER LATCH MECHANISM AND PORTABLE ELECTRONIC DEVICE USING SAME

(75) Inventors: QING GUO, Shenzhen City (CN); CHIH-CHIANG CHANG, Shindian (TW); ZHI LI, Shenzhen City (CN); SI-QUAN CHEN, Shenzhen City (CN); ZHI-YUN SHEN, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/254,097

(22) Filed: Oct. 20, 2008

(30) Foreign Application Priority Data
May 23, 2008 (CN) 200810301730.X

(51) Int. Cl. H05K 5/02

(52) U.S. Cl. 361/679.58

(57) ABSTRACT

A battery cover latch mechanism (10) used in a portable electronic device (100) is described including a cover member (11), a housing member (12), a latching assembly (13), and a return member (136). The latching assembly slides between a released position and a latched position. The return member is secured to the cover member including an elastic sheet (1361) integrally formed with the latching assembly. The elastic sheet is used to bias the latching assembly towards the latched position.

### BACKGROUND

1. Field of the Invention

The invention relates to battery cover latch mechanisms used in portable electronic devices.

2. Description of related art

Portable electronic devices usually include latch mechanisms used to latch battery covers to housings. The latch mechanisms must tolerate frequent installation and removal of batteries relative to the housings.

A typical battery cover latch mechanism includes at least one spring to facilitate the operation thereof. However, the spring may easily wear out after repeated operation and, thus the battery cover latch mechanism may fail.

Therefore, there is room for improvement within the art.

### BRIEF DESCRIPTION OF THE DRAWINGS

Many aspects of the exemplary battery cover latch mechanism and a portable electronic device using the battery cover latch mechanism can be better understood with reference to the following drawings. These drawings are not necessarily drawn to scale, the emphasis instead being placed upon clearly illustrating the principles of the exemplary battery cover latch mechanism and the portable electronic device. Moreover, in the drawings like reference numerals designate corresponding parts throughout the several views. Wherever possible, the same reference numbers are used throughout the drawings to refer to the same or like elements of an embodiment.

FIG. 1 is an exploded, isometric view of a portable electronic device incorporating a battery cover latch mechanism according to the exemplary embodiment.

FIG. 2 is similar to FIG. 1 viewed from another angle.

FIG. 3 is an isometric view of the battery cover latch mechanism at a latched position.

FIG. 4 is a sectional view of the battery cover latch mechanism shown in FIG. 4.

FIG. 5 is similar to FIG. 4 but showing a released position.

### DETAILED DESCRIPTION OF THE EXEMPLARY EMBODIMENTS

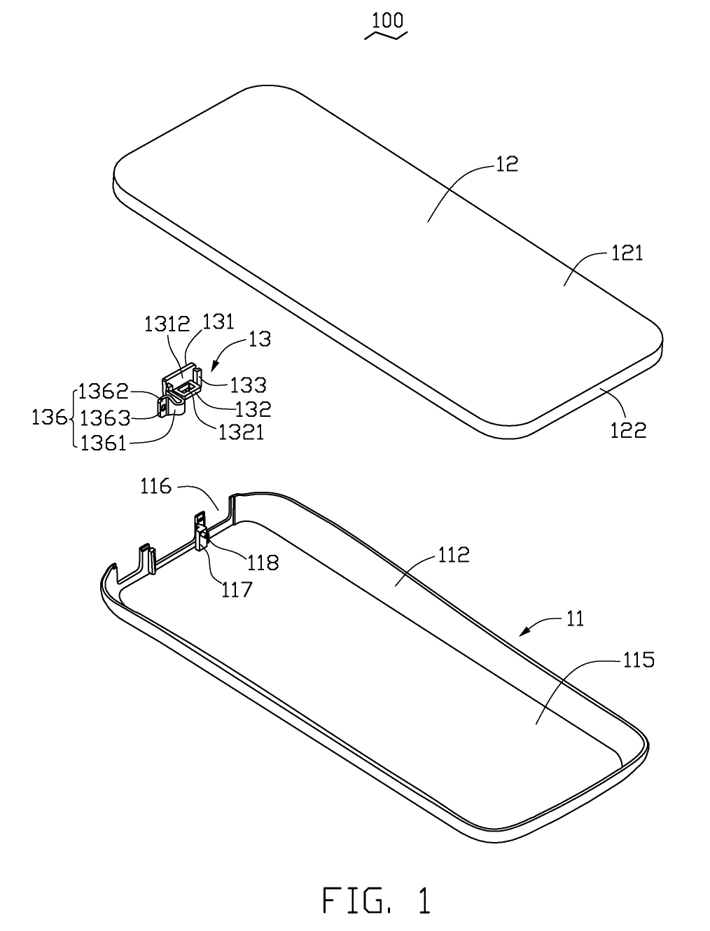

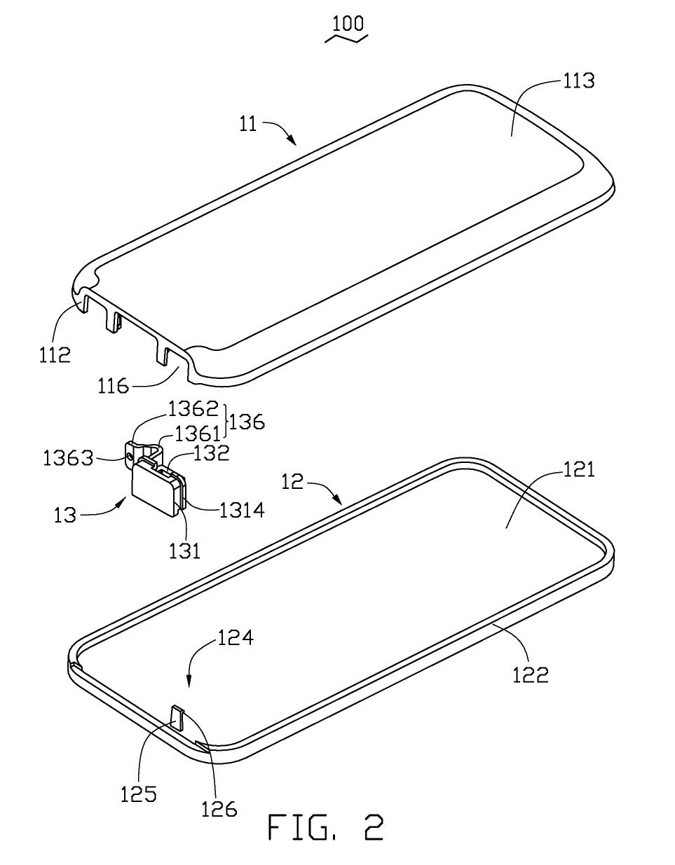

FIGS. 1 and 2 show a portable electronic device 100 including the battery cover latch mechanism including a cover member 11, a housing member 12, a latching assembly 13, and a return member 136. The housing member 12 can be a housing of the portable electronic device 100. The cover member 11 can be a cover of the portable electronic device 100. The latching assembly 13 is configured to be mounted between the housing member 11 and the cover member 12 for latching the cover member 12 to the housing member 11. The return member 136 is integrally formed with the latching assembly 13 and used to facilitate the latching of the latching member 13.

The cover member 11 has a first peripheral wall 112, a bottom wall 113 (shown in FIG. 2), and a battery chamber 115. The first peripheral wall 112 surrounds the battery chamber 115. The battery chamber 115 can accommodate a battery (not shown). One end of first peripheral wall 112 defines a generally rectangular notch 116. The bottom wall 113 has a mounting block 117 formed thereon, near the notch 116. The mounting block 117 has a mounting column 118 protruding toward the battery chamber 115.

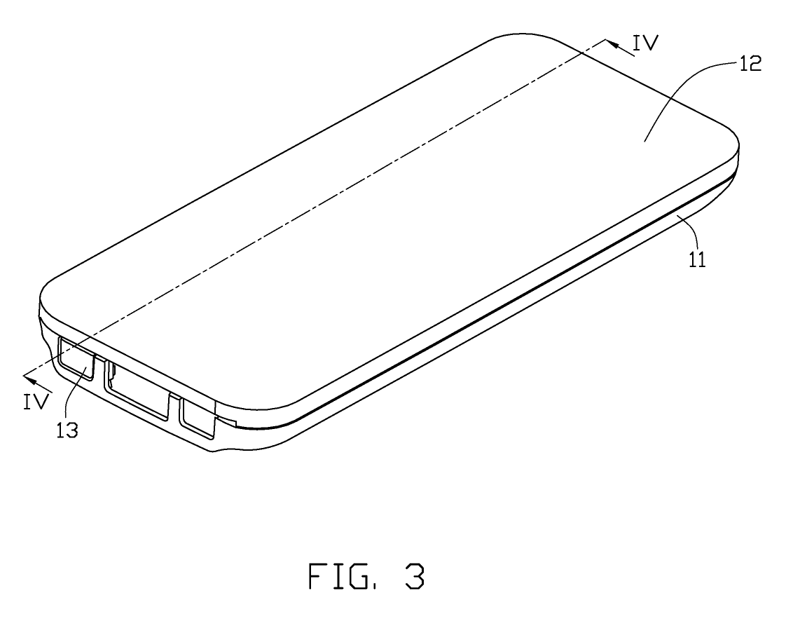

The housing member 12 includes an upper wall 121 and a second peripheral wall 122. The second peripheral wall 122 is configured to mate with the first peripheral wall 112 (best shown in FIG. 3). Referring also to FIG. 2, one end of the upper wall 121 forms a generally L-shaped claw 124 near the second peripheral wall 122. The claw 124 has a connecting portion 125 and a first claw portion 126. The connecting portion 125 connects the first claw portion 126 to the upper wall 121.

The latching assembly 13 includes a pressing portion 131, a second claw portion 132, and two retaining portions 133. The second claw portion 132 and the two retaining portions 133 protrude from the same side of the pressing portion 131. The second claw portion 132 is located between the two retaining portions 133.

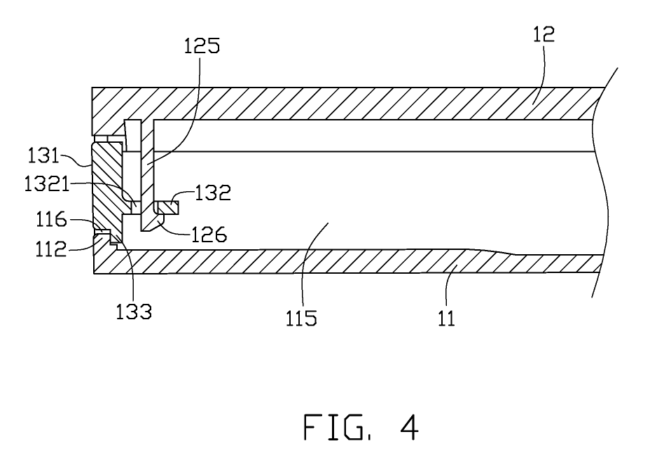

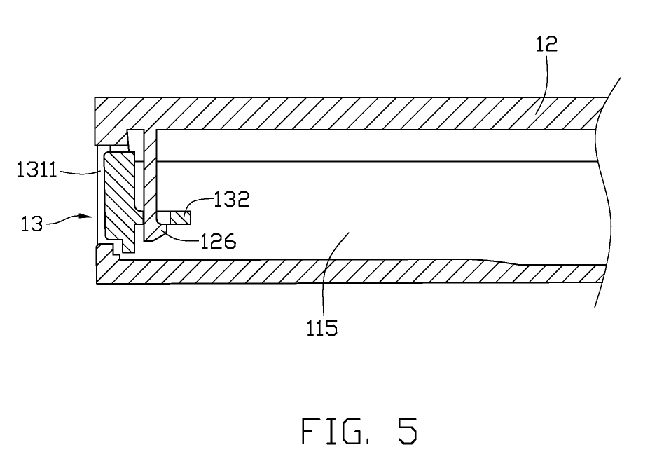

Referring to FIGS. 4 and 5, the pressing portion 131 is configured to be received in the notch 116 and slide within the notch 116. The retaining portions 133 are generally L-shaped and functioned to prevent the pressing portion 131 from falling out from the notch 116. The second claw portion 132 corresponds to the claw 124 and is configured to interlock with the claw 124. The second claw portion 132 is generally rectangular having a hole 1321 defined. The hole 1321 is configured to pass the claw 124 through.

The return member 136 includes a mounting portion 1362 connecting an elastic sheet 1361. The mounting portion 1362 defines a mounting hole 1363 corresponding to the mounting column 118. The mounting portion 1362 can be secured to the mounting block 117 by e.g., a hot melting of the mounting columns 118 within the mounting hole 1363. The elastic sheet 1361 includes a bent portion and, thus can be elastically deformed relative to the mounting portion 1362. The elastic sheet 1361 is integrally formed with one of the two retaining portions 133 and positioned between the mounting portion 1362 and the retaining portion 133.

Referring to FIGS. 3 and 4, the battery cover latch mechanism is at a latched position. The cover member 11 is latched to the housing member 12 by the interlocking of the first claw portion 126 and the second claw portion 132. The connecting portion 125 is partially received in the hole 1321. The elastic sheet 1361 is elastically deformed to bias the pressing portion 131 away from the notch 116. Oppositely, the pressing portion 131 is secured within the notch 116 by the biasing of the interior surface of the first peripheral wall 112 against the retaining portions 133.

Referring further to FIG. 5, when the cover member 11 needs to be released from the housing member 12, the pressing portion 131 is pressed further into the notch 116. During this stage, the second claw portion 132 is moved away from the first claw portion 126 until they are no longer interlocked. The elastic sheet 1361 is continuously deformed. As the interlocking is removed, the first claw portion 126 can pass through the hole 1321. Thus, the cover member 11 can be simply pulled apart from the housing member 12 along with the first claw portion 126 passing through the hole 1321.

Concerning the latching the cover member 11 to the housing member 12, the principle is similar to the above releasing process, but in reverse.

It is to be understood, however, that even through numerous characteristics and advantages of the exemplary invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A battery cover latch mechanism, comprising:
a cover member;
a housing member;
a latching assembly positioned between the cover member and the housing member and, configured for sliding between a released position and a latched position; and
a return member secured to the cover member, comprising an elastic sheet integrally formed with the latching assembly, the elastic sheet configured for biasing the latching assembly towards the latched position.

2. The battery cover latch mechanism as claimed in claim 1, wherein the housing member comprises a claw including a first claw portion, the latching assembly comprises a second claw portion defining a hole, and the first claw portion configured for passing through the hole to interlock with the second claw portion.

3. The battery cover latch mechanism as claimed in claim 2, wherein the housing member further comprises a wall, and the claw further comprises a connecting portion connecting the first claw portion to the wall.

4. The battery cover latch mechanism as claimed in claim 3, wherein the hole is configured for allowing the first claw portion to pass through and partially receive the connecting portion therein.

5. The battery cover latch mechanism as claimed in claim 1, wherein the return member further comprises a mounting portion, the elastic sheet positioned between the mounting portion and the latching assembly, the mounting portion secured to the cover member, and the elastic sheet deformable relative to the mounting portion.

6. The battery cover latch mechanism as claimed in claim 5, wherein the cover member comprises a mounting block;
the cover member defining a notch positioning the latching assembly therein; and
the mounting portion secured to the mounting block opposite to the notch.

7. The battery cover latch mechanism as claimed in claim 6, wherein the mounting portion comprises a mounting hole, and the mounting block has a mounting column formed thereon secured within the mounting hole.

8. The battery cover latch mechanism as claimed in claim 7, wherein the elastic sheet includes a bent portion, the latching assembly further comprises a retaining block, the elastic sheet integrally formed with the retaining block.

9. The battery cover latch mechanism as claimed in claim 8, wherein the latching assembly further comprises a pressing portion, the retaining block formed on the pressing portion;
the cover member comprises a peripheral wall, the notch defined through the peripheral wall; and
the pressing portion is positioned in the notch and can slide within the notch.

10. A portable electronic device, comprising:
a cover;
a housing;
a battery cover latch mechanism comprising:
a latching assembly positioned between the cover and the housing and, configured for sliding from between a released position and a latched position;
a return member secured to the cover, comprising an elastic sheet integrally formed with the latching assembly, the elastic sheet configured for biasing the latching assembly towards the latched position.

11. The portable electronic device as claimed in claim 10, wherein the housing member comprises a claw including a first claw portion, the latching assembly comprises a second claw portion defining a hole, and the first claw portion configured for passing through the hole to interlock with the second claw portion.

12. The portable electronic device as claimed in claim 11, wherein the housing member further comprises a wall, and the claw further comprises a connecting portion connecting the first claw portion to the wall.

13. The portable electronic device as claimed in claim 12, wherein the hole is configured for allowing the first claw portion to pass through and partially receive the connecting portion therein.

14. The portable electronic device as claimed in claim 10, wherein the return member further comprises a mounting portion, the elastic sheet positioned between the mounting portion and the latching assembly, the mounting portion secured to the cover member, and the elastic sheet deformable relative to the mounting portion.

15. The portable electronic device as claimed in claim 14, wherein the cover member comprises a mounting block;
the cover member defining a notch positioning the latching assembly therein; and
the mounting portion secured to the mounting block opposite to the notch.

16. The portable electronic device as claimed in claim 15, wherein the mounting portion comprises a mounting hole, and the mounting block has a mounting column formed thereon secured within the mounting hole.

17. The portable electronic device as claimed in claim 16, wherein the elastic sheet includes a bent portion, the latching assembly further comprises a retaining block, the elastic sheet integrally formed with the retaining block.

18. The portable electronic device as claimed in claim 17, wherein the latching assembly further comprises a pressing portion, the retaining block formed on the pressing portion;
the cover member comprises a peripheral wall, the notch defined through the peripheral wall; and
the pressing portion is positioned in the notch and can slide within the notch.
